(19) United States
(12) Patent Application Publication
(10) Pub. No.: US 2023/0166964 A1
(43) Pub. Date: Jun. 1, 2023

(54) MEMS SENSOR AND MEMS SENSOR MANUFACTURING METHOD

(71) Applicant: ROHM CO., LTD., Kyoto (JP)

(72) Inventors: Nobuhisa YAMASHITA, Kyoto (JP); Toma FUJITA, Kyoto (JP); Martin Wilfried HELLER, Kyoto (JP)

(73) Assignee: ROHM CO., LTD., Kyoto (JP)

(21) Appl. No.: 17/989,492

(22) Filed: Nov. 17, 2022

(30) Foreign Application Priority Data
Nov. 30, 2021 (JP) 2021-194811

(51) Int. Cl. B81B 3/00; B81C 1/00; G01P 15/08; G01P 15/125

(52) U.S. Cl. CPC B81B 3/0072; B81C 1/00666; G01P 15/0802; G01P 15/125; B81B 2201/0235; B81B 2203/0136; B81B 2203/04; B81B 2207/07; B81C 2203/0109

(57) ABSTRACT

A MEMS sensor includes: a conductive device-side substrate including cavity in thickness direction thereof; a MEMS electrode arranged in the cavity; a support extending in first direction toward the MEMS electrode from peripheral wall of the cavity and connected to and support the MEMS electrode; and an isolator traversing the support in second direction in plan view to isolate the support into a first support on the side of the MEMS electrode and a second support on the side of the device-side substrate to be electrically insulated from each other in the first direction, wherein the isolator includes: a trench recessed in the thickness direction with respect to the device-side substrate; insulating layers formed on inner wall surfaces of the trench; and joining layers formed on the insulating layers and including portions facing each other and at least partially joined to each other in the first direction.

### CROSS-REFERENCE TO RELATED APPLICATION

This application is based upon and claims the benefit of priority from Japanese Patent Application No. 2021-194811, filed on Nov. 30, 2021, the entire contents of which are incorporated herein by reference.

### TECHNICAL FIELD

The present disclosure relates to a MEMS sensor and a MEMS sensor manufacturing method.

### BACKGROUND

In the related art, there is known an acceleration sensor including a comb-like fixed electrode and a comb-like movable electrode formed of a part of a device substrate. An insulating film is embedded in a base end of each tooth of the fixed electrode and the movable electrode.

The insulating film forms an isolator that electrically insulates each tooth of the fixed electrode and the movable electrode. The isolator performs a function of electrically insulating portions located on both sides of the isolator, and also performs a function of mechanically connecting the portions. In other words, the isolator may also be called an isolation joint.

The isolator is configured by forming a trench recessed in the device substrate in a thickness direction thereof and extending in a direction that traverses the electrode in a plan view, and forming an insulating layer on an inner wall surface of the trench. The insulating layer is circumferentially continuous along an inner peripheral wall surface of the trench in the plan view. At a central portion in a width direction of the isolator, insulating layers face each other in the width direction, and a seam extending along the trench is formed. The isolator may be broken along the seam.

### SUMMARY

Some embodiments of the present disclosure provide a MEMS sensor and a MEMS sensor manufacturing method capable of suppressing breakage of an isolator along a seam.

According to an embodiment of the present disclosure, there is provided a MEMS sensor, which includes: a conductive device-side substrate including a cavity in a thickness direction of the conductive device-side substrate; a MEMS electrode arranged in the cavity; a support extending in a first direction toward the MEMS electrode from a peripheral wall of the cavity and connected to the MEMS electrode to support the MEMS electrode; and an isolator configured to traverse the support in a second direction intersecting the first direction in a plan view to isolate the support into a first support on the side of the MEMS electrode and a second support on the side of the device-side substrate such that the first support and the second support are electrically insulated from each other in the first direction, wherein the isolator includes: a trench recessed in the thickness direction with respect to the device-side substrate; insulating layers formed on inner wall surfaces of the trench; and joining layers formed on the insulating layers and including portions facing each other in the first direction and at least partially joined to each other in the first direction.

### BRIEF DESCRIPTION OF DRAWINGS

The accompanying drawings, which are incorporated in and constitute a part of the specification, illustrate embodiments of the present disclosure.

FIG. 1 is a schematic plan view of a MEMS sensor according to an embodiment of the present disclosure.

FIG. 2 is a cross-sectional view taken along line II-II in FIG. 1.

FIG. 3 is a cross-sectional view showing a part of a manufacturing process of a device-side substrate assembly.

FIG. 4 is a cross-sectional view of the device-side substrate assembly showing a next step of FIG. 3.

FIG. 5 is a cross-sectional view of the device-side substrate assembly showing a next step of FIG. 4.

FIG. 6 is an enlarged view of part A in FIG. 5.

FIG. 7 is a cross-sectional view of a trench taken along line VII-VII in FIG. 6.

FIG. 8 is a cross-sectional view of the device-side substrate assembly showing a next step of FIG. 5.

FIG. 9 is a cross-sectional view of the trench taken along line IX-IX in FIG. 8.

FIG. 10 is a cross-sectional view of the device-side substrate assembly showing a next step of FIG. 8.

FIG. 11 is a cross-sectional view of the trench taken along line XI-XI in FIG. 10.

FIG. 12 is a cross-sectional view of the device-side substrate assembly showing a next step of FIG. 10.

FIG. 13 is a cross-sectional view of the device-side substrate assembly showing a next step of FIG. 12.

FIG. 14 is a cross-sectional view of the device-side substrate assembly showing a next step of FIG. 13.

FIG. 15 is a cross-sectional view of the device-side substrate assembly showing a next step of FIG. 14.

FIG. 16 is a cross-sectional view of the device-side substrate assembly showing a next step of FIG. 15.

FIG. 17 is a cross-sectional view of the device-side substrate assembly showing a next step of FIG. 16.

FIG. 18 is a cross-sectional view showing a part of a manufacturing process of a lid-side substrate assembly.

FIG. 19 is a cross-sectional view of the lid-side substrate assembly showing a next step of FIG. 18.

FIG. 20 is a cross-sectional view of the lid-side substrate assembly showing a next step of FIG. 19.

FIG. 21 is a cross-sectional view of the lid-side substrate assembly showing a next step of FIG. 20.

FIG. 22 is a cross-sectional view showing a part of a process of joining the lid-side substrate assembly to the device-side substrate assembly.

FIG. 23 is a cross-sectional view of the device-side substrate assembly and the lid-side substrate assembly showing a next step of FIG. 22.

### DETAILED DESCRIPTION

Hereinafter, embodiments of the present disclosure will be described with reference to the accompanying drawings. It should be noted that the following description is merely an example, and does not limit the present disclosure, its applications, or its uses. Moreover, the drawings are schematic, and ratios of respective dimensions are different from actual ratios.

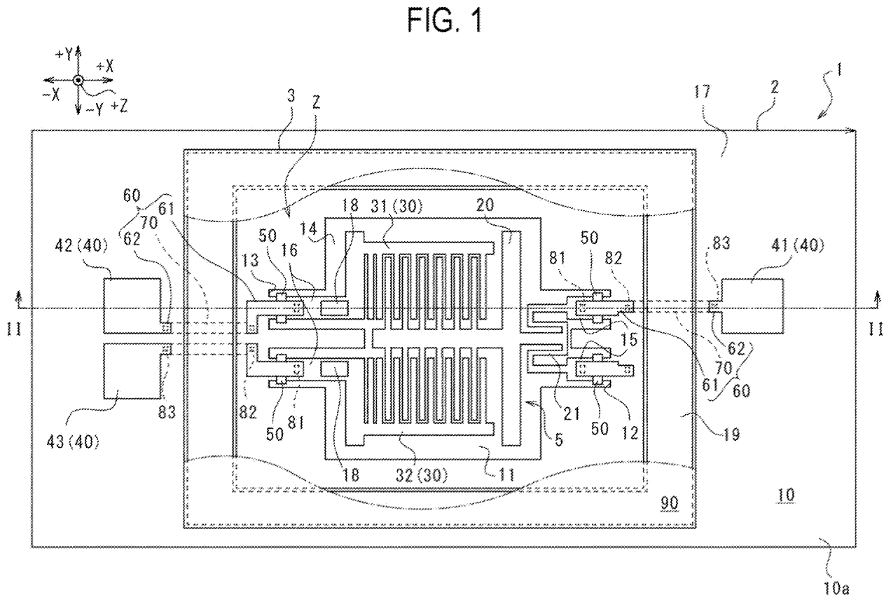

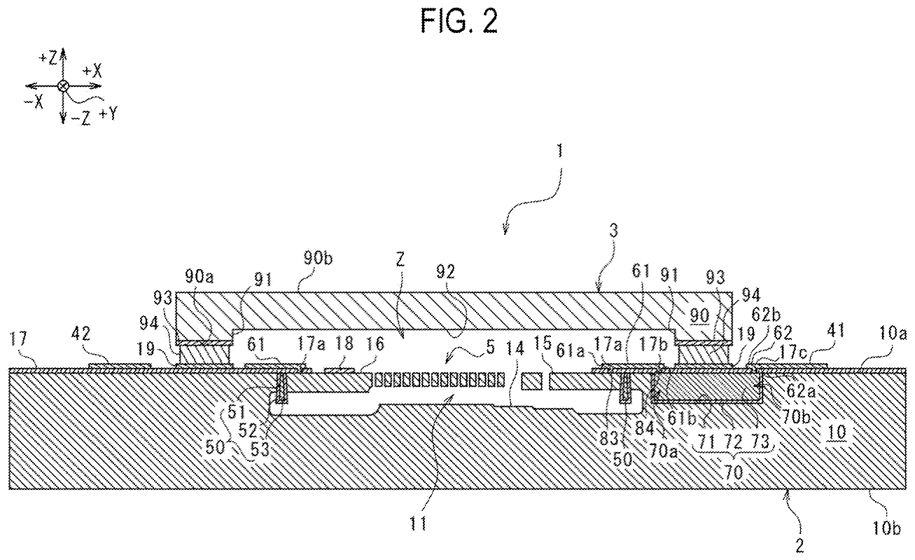

FIG. 1 is a plan view schematically showing a MEMS sensor 1 according to an embodiment of the present disclosure. FIG. 2 is a cross-sectional view taken along line II-II in FIG. 1. The MEMS sensor 1 according to the present embodiment is a capacitive acceleration sensor. Referring to FIGS. 1 and 2, the MEMS sensor 1 includes a device-side substrate assembly 2 including a sensor 5, and a lid-side substrate assembly 3 joined to the device-side substrate assembly 2 to form an accommodation space Z in which the sensor 5 is accommodated between the device-side substrate assembly 2 and the lid-side substrate assembly 3. In FIG. 1, the lid-side substrate assembly 3 is shown in a partially transparent state.

The device-side substrate assembly 2 includes a device-side substrate 10 formed in a rectangular shape in a plan view. In the following description, for the sake of convenience, when seen in a plan view, a longitudinal direction of the device-side substrate 10 is referred to as an X direction, a lateral direction of the device-side substrate 10 is referred to as a Y direction, and a thickness direction of the device-side substrate 10 is referred to as a Z direction. In other words, the Y direction is orthogonal to the X direction in a plan view, and the Z direction is orthogonal to both the X direction and the Y direction. In FIG. 1, the right side is referred to as +X direction, the left side is referred to as −X direction, the upper side is referred to as +Y direction, and the lower side is referred to as −Y direction. In FIG. 2, the upper side is referred to as +Z direction, and the lower side is referred to as −Z direction.

The lid-side substrate assembly 3 includes a lid-side substrate 90 which is smaller than the device-side substrate 10 in the X direction.

The device-side substrate 10 is constituted by a conductive silicon substrate. As shown in FIG. 2, the device-side substrate 10 includes a first main surface 10a on the +Z-direction side and a second main surface 10b on the −Z-direction side. The device-side substrate 10 includes a cavity 11 recessed in the −Z direction with respect to the first main surface 10a.

As shown in FIG. 1, Y-direction central portions of the cavity 11 at both ends in the X direction are partitioned by a first peripheral wall 12 and a second peripheral wall 13 extending in the Y direction and the Z direction, and a bottom of the cavity 11 is partitioned by a bottom wall 14 extending in the X direction and the Y direction.

The first peripheral wall 12 of the cavity 11 is formed with a first support 15 extending in the −X direction and connected to the sensor 5 to support the sensor 5 from the +X-direction side. The second peripheral wall 13 of the cavity 11 is formed with a second support 16 extending in the +X direction and connected to the sensor 5 to support the sensor 5 from the −X-direction side. Each of the first support 15 and the second support 16 is formed in a pair in the Y direction by a part of the device-side substrate 10.

As shown in FIG. 2, the sensor 5 is arranged on a surface layer of the cavity 11 on the side of the first main surface 10a . As shown in FIG. 1, the sensor 5 is a MEMS electrode formed on a part of the device-side substrate 10. Specifically, the sensor 5 includes a comb-like movable electrode 20 positioned on the +X-direction side and a comb-shaped fixed electrode 30 positioned on the −X-direction side and combined with each tooth of the movable electrode 20. The movable electrode 20 is supported by the first support 15 in a floating state in the +Z direction with respect to the bottom wall 14. The fixed electrode 30 is supported by the second support 16 in a floating state in the +Z direction with respect to the bottom wall 14.

The movable electrode 20 includes a spring mechanism 21 formed by a part of the device-side substrate 10 at the +X-direction end. The movable electrode 20 may be displaced in the X direction, the Y direction, and the Z direction via the spring mechanism 21. The spring mechanism 21 is branched into two ends on the +X-direction side, each of which is connected to a pair of first supports 15.

The fixed electrode 30 includes a first fixed electrode 31 positioned on a +Y-direction half portion and a second fixed electrode 32 positioned on a −Y-direction half portion. Each of the first fixed electrode 31 and the second fixed electrode 32 is connected to a pair of second supports 16. An oxide film 18 is formed on a +Z-direction surface of each of the pair of second supports 16. The oxide film 18 allows the first fixed electrode 31 and the second fixed electrode 32 to bend in the Z direction, which improves detectability of changes in capacitance in the Z direction by the sensor 5.

In the sensor 5, when the movable electrode 20 is displaced due to acceleration, the change in capacitance between the movable electrode 20 and the fixed electrode 30 corresponding to the displacement of the movable electrode 20 is taken out as an electric signal from a pad 40, which will be described later.

An isolator 50 is formed in each of the pair of first supports 15 to isolate the first support 15 into a first portion on the side of the MEMS electrode and a second portion on the side of the device-side substrate 10 to electrically insulate the first portion and the second portion in the X direction. The isolator 50 extends in the X direction to traverse the first support 15 in a plan view. As shown in FIG. 2, the isolator 50 extends from a front surface (on the side of +Z direction) to a rear surface (on the side of −Z direction) of the first support 15, and protrudes into the cavity 11 in the −Z direction, in the present embodiment.

The isolator 50 includes a trench 51 recessed in the Z direction with respect to the device-side substrate 10, trench insulating layers 52 continuously formed on inner wall surfaces of the trench 51 in a circumferential direction thereof, and trench joining layers 53 continuously formed on the trench insulating layers 52 in the circumferential direction. At least portions of the trench joining layers 53 facing each other in the X direction are joined to each other. The trench insulating layers 52 are formed of silicon oxide films. The trench joining layers 53 are formed of polysilicon. The trench joining layers 53 are joined to each other at least on the side of the first main surface 10a of the device-side substrate 10 in the trenches 51.

As shown in FIG. 1, each of the pair of second supports 16 is similarly formed with an isolator 50 that electrically insulates the second supports 16 in the X direction. In the second support 16, the isolator 50 is located on the −X-direction side of the oxide film 18.

A main insulating layer 17 is formed on the first main surface 10a of the device-side substrate 10 in a region excluding the movable electrode 20 and the fixed electrode 30. The main insulating layer 17 is, for example, a silicon oxide film. A plurality of pads 40 are formed on the main insulating layer 17 outside the accommodation space Z. The pad 40 is an electrode pad having conductivity. The pad 40 is formed of AlSi in the present embodiment. The pad 40 is electrically connected to the sensor 5 via a conductive path 60.

The pad 40 includes a first pad 41 positioned at the +X-direction end, a second pad portion 42 positioned on the +Y-direction side at the −X-direction end, and a third pad 43 positioned on the −Y-direction side at the −X-direction end. The first pad 41, the second pad 42, and the third pad 43 are electrically connected to the movable electrode 20, the first fixed electrode 31, and the second fixed electrode 32, respectively, via the conductive path 60.

The conductive path 60 connecting the first pad 41 and the movable electrode 20 will be described below as an example. The conductive path 60 includes a MEMS electrode wiring 61 connected to the sensor 5, a pad wiring 62 connected to the pad 40, and an inner conductive path 70 connecting the MEMS electrode wiring 61 and the pad wiring 62.

As shown in FIG. 2, the MEMS electrode wiring 61 is formed on the main insulating layer 17 in the accommodation space Z. The MEMS electrode wiring 61 extends in the X direction and includes a MEMS electrode wiring first end 61a positioned on the sensor 5 side and a MEMS electrode wiring second end 61b positioned on the opposite side to the sensor 5. The MEMS electrode wiring first end 61a faces a portion of the first support 15 positioned closer to the sensor 5 than the isolator 50 in the Z direction with the main insulating layer 17 interposed therebetween. The MEMS electrode wiring second end 61b faces a portion positioned on the opposite side of the isolator 50 from the sensor 5 in the Z direction with the main insulating layer 17 interposed therebetween. That is, the MEMS electrode wiring 61 traverses the isolator 50 in the X direction in a plan view.

The pad wiring 62 is formed on the main insulating layer 17 outside the accommodation space Z. The pad wiring 62 extends in the X direction and includes a pad wiring first end 62a connected to the first pad 41 and a pad wiring second end 62b positioned on the side of the sensor 5.

The inner conductive path 70 includes a trench 71 extending in the X direction from the inside to the outside of the accommodation space Z and recessed in the −Z direction with respect to the first main surface 10a of the device-side substrate 10, trench insulating layers 72 formed on the inner wall surfaces of the trench 71, and trench conductive layers 73 formed on the trench insulating layers 72. The inner conductive path 70 includes an inner conductive path first end 70a positioned inside the accommodation space Z and an inner conductive path second end 70b positioned outside the accommodation space Z. The inner conductive path first end 70a faces the MEMS electrode wiring second end 61b in the Z direction in a plan view. The inner conductive path second end 70b faces the pad wiring second end 62b in the Z direction in a plan view.

The trench insulating layers 72 are silicon oxide films. The trench conductive layers 73 are formed of conductive polysilicon. The inner conductive path 70 is formed to be flush with the first main surface 10a of the device-side substrate 10 in the Z direction.

A first contact hole 17a penetrating in the Z direction at a position facing the MEMS electrode wiring first end 61a, a second contact hole 17b penetrating in the Z direction at a position between the MEMS electrode wiring second end 61b and the inner conductive path first end 70a, and a third contact hole 17c penetrating in the Z direction at a position between the pad wiring second end 62b and the inner conductive path second end 70b are formed in the main insulating layer 17.

A first contact 81 is embedded in the first contact hole 17a . A second contact 82 is embedded in the second contact hole 17b . A third contact 83 is embedded in the third contact hole 17c. The first to third contacts 81 to 83 are conductive members. The first to third contacts 81 to 83 are formed of AlSi in the present embodiment.

Therefore, the MEMS electrode wiring 61 is connected to the sensor 5 via the first contact 81 and connected to the inner conductive path 70 via the second contact 82. The pad wiring 62 is connected to the inner conductive path 70 via the third contact 83. Accordingly, the conductive path 60 includes the MEMS electrode wiring 61 on the main insulating layer 17 inside the accommodation space Z, the inner conductive path 70 extending from the inside to the outside of the housing space Z and positioned inside the device-side substrate 10 in the thickness direction thereof, that is, embedded in the device-side substrate 10, and the pad wiring 62 on the main insulating layer 17 outside the accommodation space Z.

As shown in FIG. 1, a bonding layer 19 is formed in a rectangular frame shape on the main insulating layer 17 along a periphery of the accommodation space Z. The bonding layer 19 traverses the inner conductive path 70 in the Y direction in a plan view. Since the inner conductive path 70 is formed to be flush with the first main surface 10a of the device-side substrate 10 as described above, the main insulating layer 17 formed over the device-side substrate 10 and the inner conductive path 70 is flat without unevenness along the first main surface 10a . As a result, the bonding layer 19 formed on the main insulating layer 17 is also flat.

As described above, the device-side substrate assembly 2 includes at least the device-side substrate 10, the sensor 5, the pad 40, the isolator 50, and the conductive path 60.

As shown in FIG. 2, the lid-side substrate 90 is constituted by a silicon substrate. The lid-side substrate 90 has a first main surface 90a facing the device-side substrate assembly 2 (−Z direction) and a second main surface 90b facing the opposite side thereof (+Z direction). The lid-side substrate 90 protrudes from the first main surface 90a in the −Z direction and includes an annular peripheral bank 91 extending along the outer peripheral edge in a plan view. In the present embodiment, the peripheral bank 91 is formed in a rectangular shape along the bonding layer 19 of the device-side substrate 10.

The lid-side substrate 90 includes a recess 92 formed inside the peripheral bank 91. The recess 92 is formed by selectively digging, in the +Z direction, a portion facing the device-side substrate 10 in the Z direction. A position and a shape of the recess 92 are not limited to those shown in FIG. 2, and may be appropriately determined in consideration of the shape of the sensor 5.

A bonding pad 93 is formed on a top surface of the peripheral bank 91 facing the −Z direction. The bonding pad 93 is formed over the entire circumference of the peripheral bank 91.

A bonding material 94 that bonds the device-side substrate assembly 2 and the lid-side substrate assembly 3 is formed in a rectangular annular shape along the peripheral bank 91. The bonding material 94 is, for example, glass frit containing conductive particles. The bonding material 94 is bonded to the bonding layer 19 for the device-side substrate assembly 2 and bonded to the bonding pad 93 for the lid-side substrate assembly 3. The device-side substrate assembly 2 and the lid-side substrate assembly 3 are joined by the bonding material 94, and the accommodation space Z in which the sensor 5 is accommodated is formed between the device-side substrate assembly 2 and the lid-side substrate assembly 3.

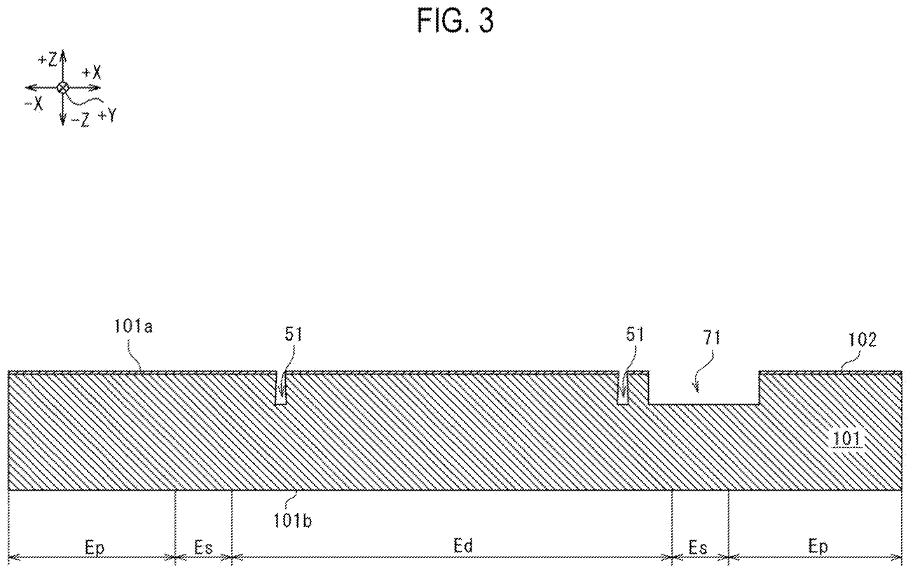

Next, a method of manufacturing the MEMS sensor 1 will be described. First, a method of manufacturing the device-side substrate assembly 2 will be described with reference to FIGS. 3 to 17. As shown in FIG. 3, a first semiconductor wafer 101, which is an original substrate of a semiconductor substrate, is provided. The first semiconductor wafer 101 is a conductive wafer, for example, a conductive silicon wafer.

The first semiconductor wafer 101 has a first main surface 101a and a second main surface 101b corresponding to the first main surface 10a and the second main surface 10b of the device-side substrate 10, respectively. Hereinafter, in the first main surface 101a of the first semiconductor wafer 101, a region corresponding to the bonding material 94 is referred to as a seal region Es, a region surrounded by the seal region Es is referred to as a device region Ed, and a region outside the seal region Es is referred to as a pad region Ep.

First, the entire first main surface 101a of the first semiconductor wafer 101 is thermally oxidized. Thus, a first thermal oxide film 102 is formed on the first main surface 101a of the first semiconductor wafer 101. The first thermal oxide film 102 is then patterned and etched to form openings in the regions where the trench 51 of the isolator 50 and the trench 71 of the inner conductive path 70 are to be formed. Then, the first semiconductor wafer 101 is dug down by anisotropic etching using the first thermal oxide film 102 as a hard mask to form the trenches 51 and 71. That is, the trench 51 of the isolator 50 and the trench 71 of the inner conductive path 70 are formed at the same time.

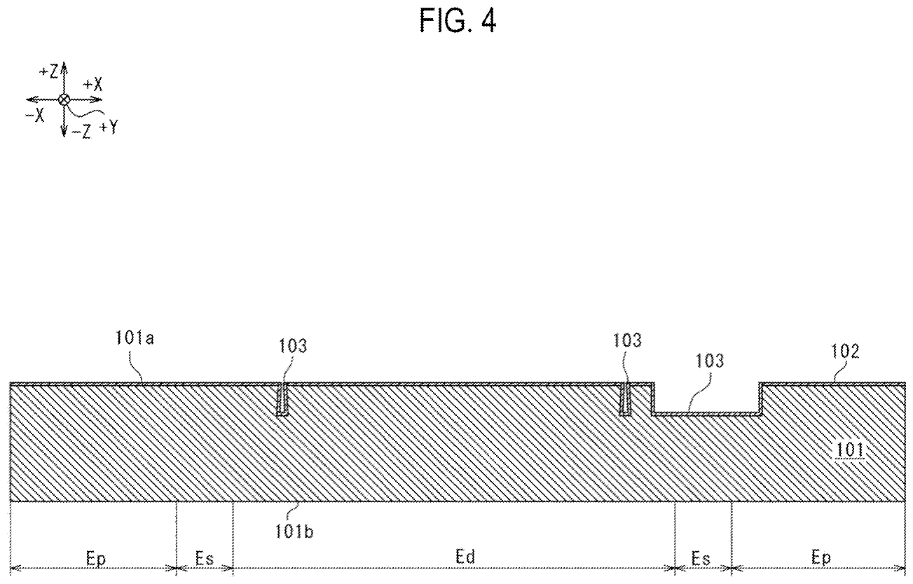

Next, as shown in FIG. 4, the inner wall surfaces of the trenches 51 and 71 are thermally oxidized to form trench thermal oxide films 103 (trench insulating layers 52 and 72) on the inner wall surfaces of the trenches 51 and 71. That is, the trench insulating layers 52 of the isolator 50 and the trench insulating layers 72 of the inner conductive path 70 are formed at the same time.

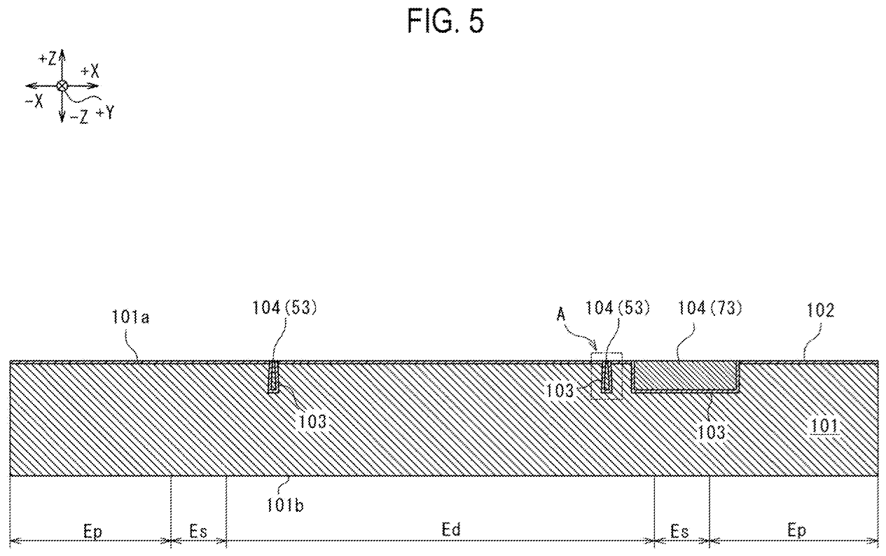

Next, as shown in FIG. 5, conductive polysilicon 104 is deposited on the entire surface of the first main surface 101a of the first semiconductor wafer 101 by CVD (Chemical Vapor Deposition). Thus, the trench joining layer 53 of the isolator 50 and the trench conductive layer 73 of the inner conductive path 70 are formed at the same time. Then, the first main surface 101a of the first semiconductor wafer 101 is polished by CMP (Chemical Mechanical Polishing) to remove the polysilicon 104 on the surface, thereby exposing the first thermal oxide film 102 on the first main surface 101a.

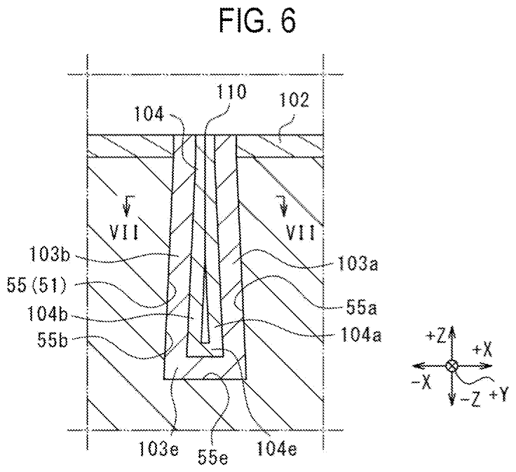

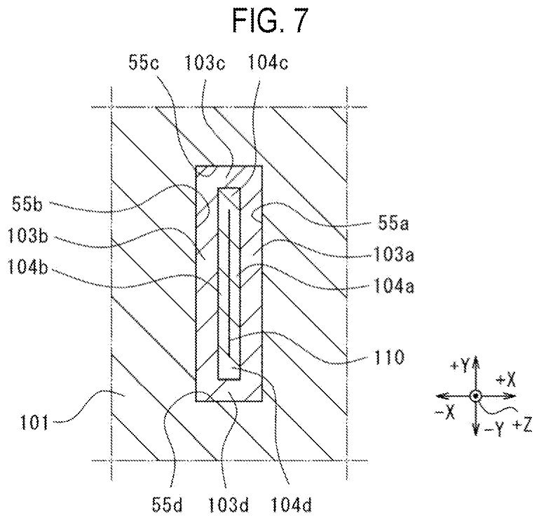

Now, the polysilicon 104 deposited on the trench thermal oxide film 103 in the trenches 51 and 71 will be described with reference to FIGS. 6 and 7. FIG. 6 is an enlarged view of part A in FIG. 5, and FIG. 7 is a cross-sectional view of the trench 51 taken along line VII-VII in FIG. 6. As shown in FIGS. 6 and 7, the trench thermal oxide film 103 is formed continuously over the inner wall surface 55 of the trench 51.

Specifically, the trench thermal oxide film 103 integrally includes a trench first thermal oxide film 103a formed on a first sidewall 55a on the +X-direction side of the trench 51, a trench second thermal oxide film 103b formed on a second sidewall 55b on the −X-direction side of the trench 51, a trench third thermal oxide film 103c formed on a third sidewall 55c on the +Y-direction side of the trench 51, a trench fourth thermal oxide film 103d formed on a fourth sidewall 55d on the −Y-direction side of the trench 51, and a trench fifth thermal oxide film 103e formed on a bottom wall 55e on the −Z-direction side of the trench 51. The trench first thermal oxide film 103a and the trench second thermal oxide film 103b are spaced apart from each other in the X direction, and the trench third thermal oxide film 103c and the trench fourth thermal oxide film 103d are spaced apart from each other in the Y direction.

The polysilicon 104 integrally includes a first polysilicon 104a deposited on the trench first thermal oxide film 103a, a second polysilicon 104b deposited on the trench second thermal oxide film 103b, a third polysilicon 104c deposited on the trench third thermal oxide film 103c, a fourth polysilicon 104d deposited on the trench fourth thermal oxide film 103d, and a fifth polysilicon 104e deposited on the trench fifth thermal oxide film 103e . In the present embodiment, the first polysilicon 104a and the second polysilicon 104b are in contact with each other in the X direction, and a seam 110 extending in the Y direction is formed by the first polysilicon 104a and the second polysilicon 104b.

In the present embodiment, an annealing process is performed to promote rearrangement and/or rejoining of the polysilicon 104. As a result, the first polysilicon 104a and the second polysilicon 104b are jointed to each other in the X direction such that the seam 110 is strongly bonded at least on the side of the first main surface 101a . Although illustration is omitted, the cross section of the trench 71 has the same configuration as the cross section of the trench 51 except that the X direction is changed to the Y direction. The description thereof is omitted.

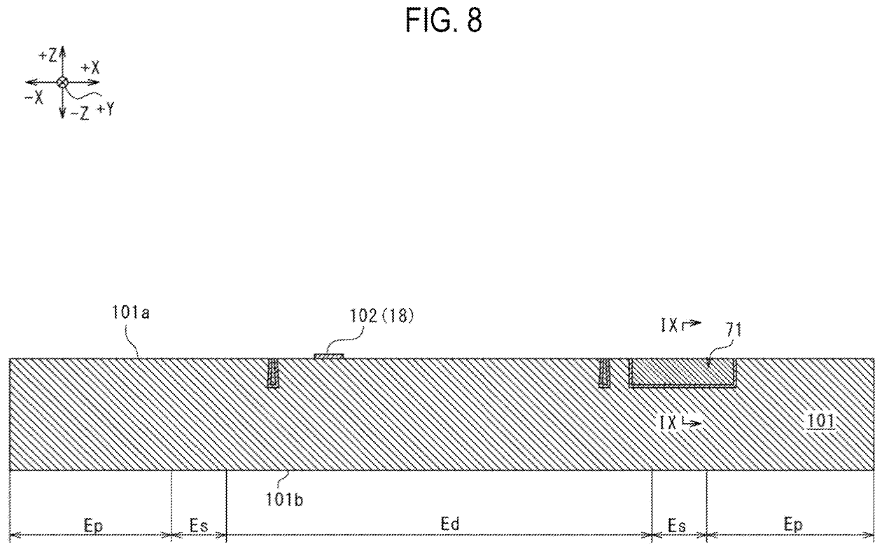

Next, as shown in FIG. 8, the first thermal oxide film 102 is patterned, and the first thermal oxide film 102 is removed by etching except for the portion corresponding to the base end of the fixed electrode 30. As a result, an oxide film 18 is formed.

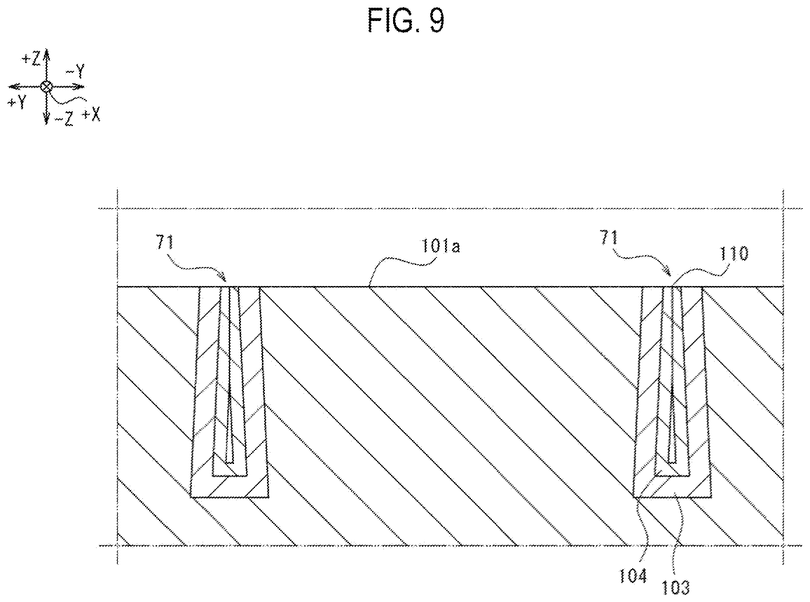

FIG. 9 is a cross-sectional view showing the trench 71 cut in the Y direction along line IX-IX in FIG. 8. As shown in FIG. 9, the surface of the trench 71 is formed to be flush with the first main surface 101a of the first semiconductor wafer 101 from which the first thermal oxide film 102 has been removed.

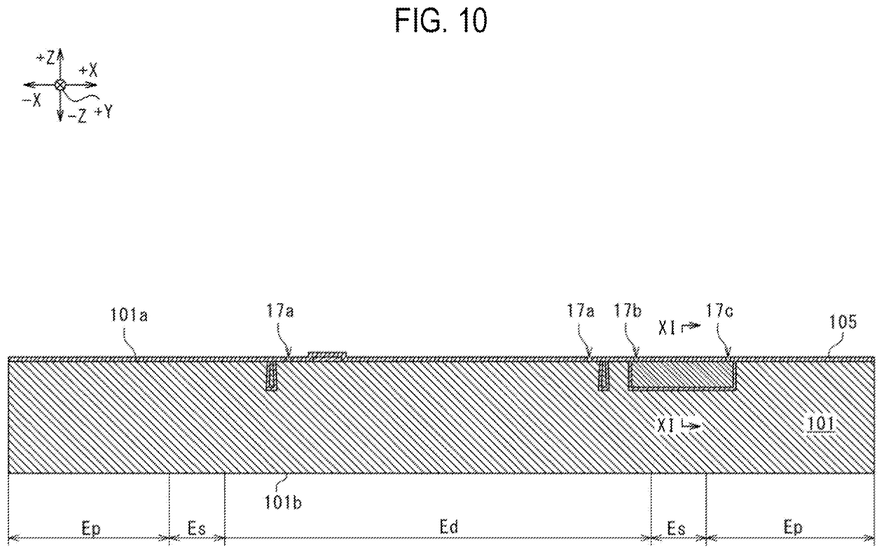

Next, as shown in FIG. 10, a first insulating film 105 (main insulating layer 17) formed of silicon oxide (SiO2) is formed on the entire surface of the first semiconductor wafer 101 on the side of the first main surface 101a by, for example, a CVD method. Then, the first insulating film 105 is selectively removed by photolithography and etching to form first to third contact holes 17a to 17c.

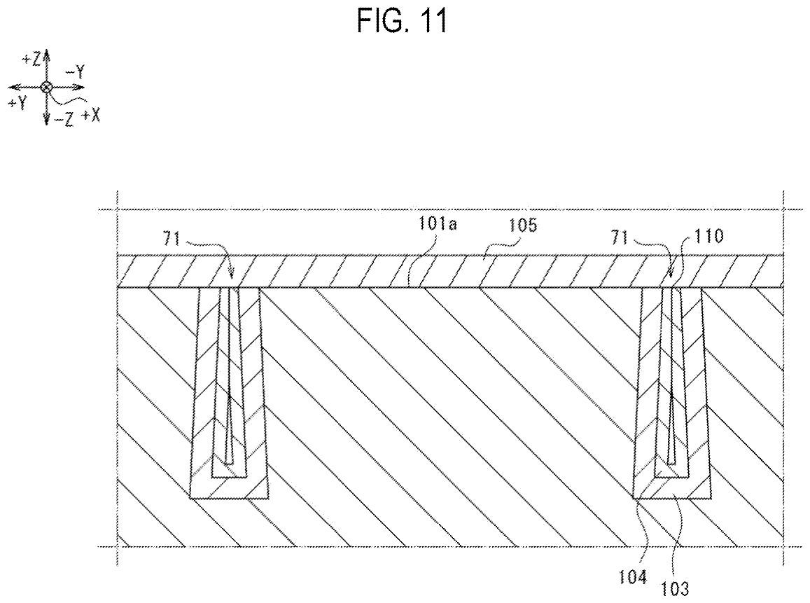

FIG. 11 is a cross-sectional view showing the trench 71 cut in the Y direction along line XI-XI in FIG. 10. As shown in FIG. 11, the first main surface 101a of the first semiconductor wafer 101 and the surface of the trench 71 are formed to be flush with each other. Therefore, the first insulating film 105 deposited over them is also formed flat. As a result, passivation coverage of the inner conductive paths 70 by the first insulating film 105 is improved, such that the inner conductive paths 70 adjacent to each other in the Y direction are prevented from being electrically connected to each other.

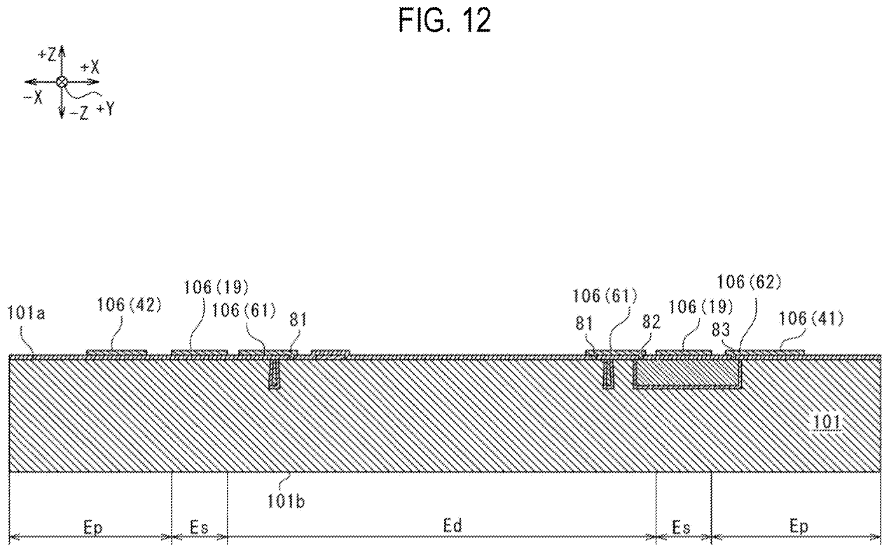

Next, as shown in FIG. 12, a metal layer 106 is deposited on the first insulating film 105 by a PVD (Physical Vapor Deposition) method. At this time, the metal layer 106 is also laminated on the first to third contact holes 17a to 17c to form first to third contacts 81 to 83. The metal layer 106 is formed of a conductive metal. The first to third contacts 81 to 83 are formed of AlSi in the present embodiment. Then, the metal layer 106 is selectively removed by photolithography and etching. A MEMS electrode wiring 61 is formed in the device region Ed, a bonding layer 19 is formed in the seal region Es, and a pad 40 and a pad wiring 62 are formed in the pad region Ep.

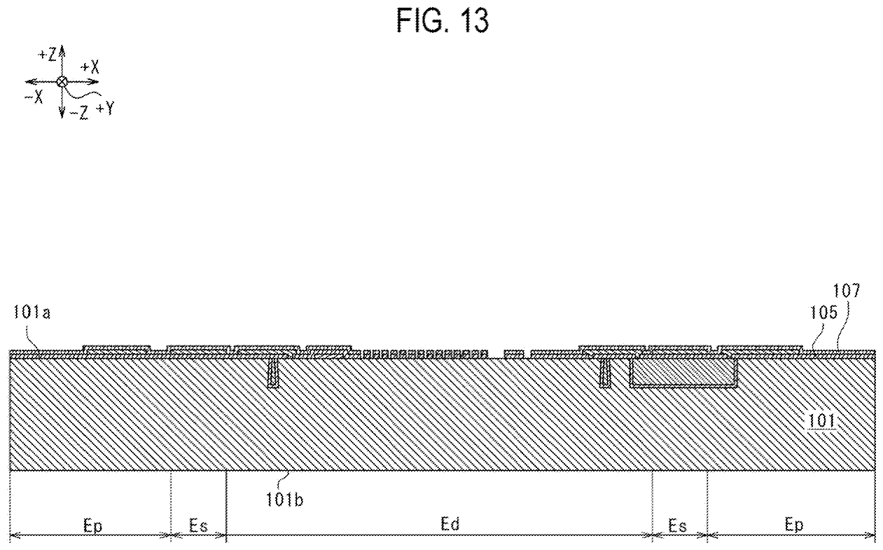

Next, as shown in FIG. 13, a second insulating film 107 formed of silicon oxide (SiO2) is formed on the entire first main surface 101a of the first semiconductor wafer 101 by, for example, a CVD method. Then, a resist including openings in regions other than predetermined regions is formed on the second insulating film 107. The predetermined regions include regions of the device region Ed in which the movable electrode 20, the fixed electrode 30, the first support 15, and the second support 16 are to be formed. By using the resist as a mask, the first insulating film 105 and the second insulating film 107 are removed by etching.

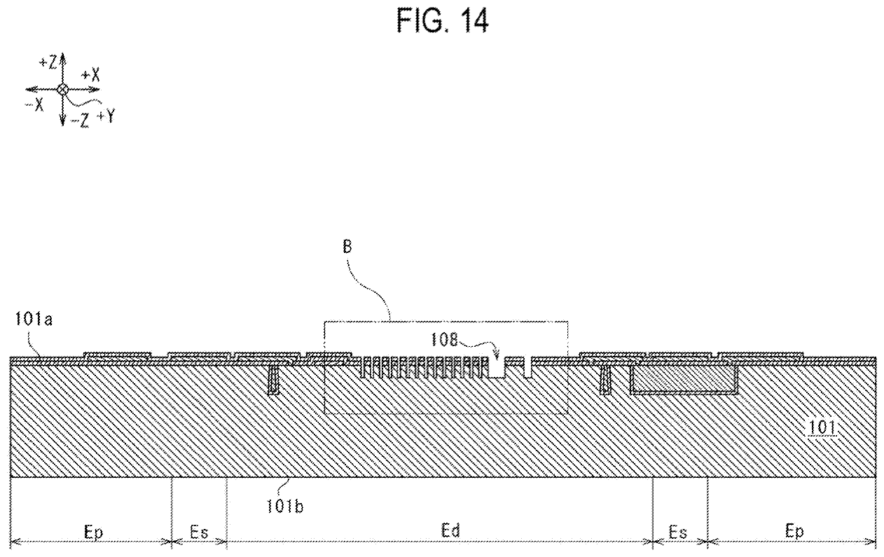

Next, as shown in FIG. 14, by using the resist as a mask, portions of the first semiconductor wafer 101 from which the first insulating film 105 and the second insulating film 107 are removed are further dug down by anisotropic etching. As a result, a surface layer of the first main surface 101a of the first semiconductor wafer 101 is formed in the shape of the movable electrode 20, the fixed electrode 30, the first support 15, and the second support 16, and a trench 108 is formed between them.

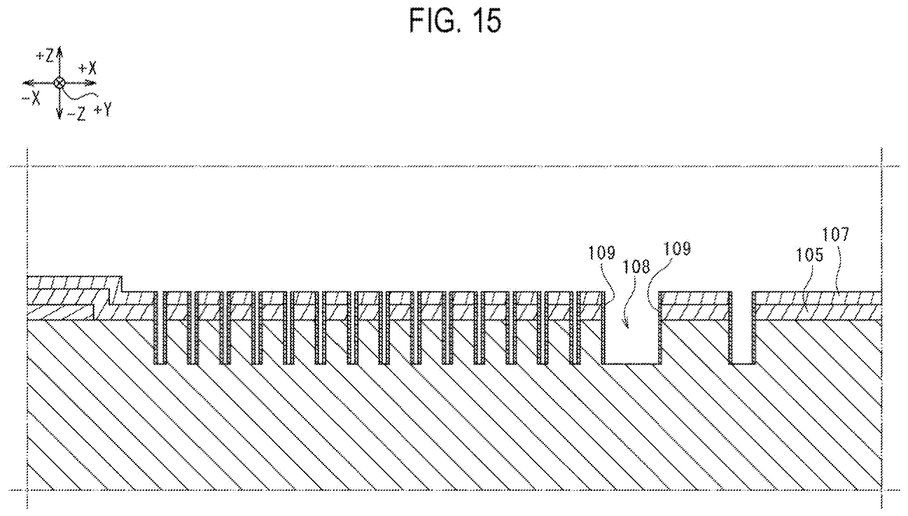

Next, as shown in FIG. 15, which is an enlarged view of part B in FIG. 14, a protective film 109 formed of silicon oxide (SiO2) is formed on the entire first main surface 101a of the first semiconductor wafer 101 and the entire inner surface of the trench 108 (the side and bottom surfaces defining the trench 108) by, for example, a CVD method. The protective film 109 is removed by etching-back except for the portions formed on the sidewalls of the trench 108. Thus, the protective film 109 is formed only on the sidewalls of the trench 108.

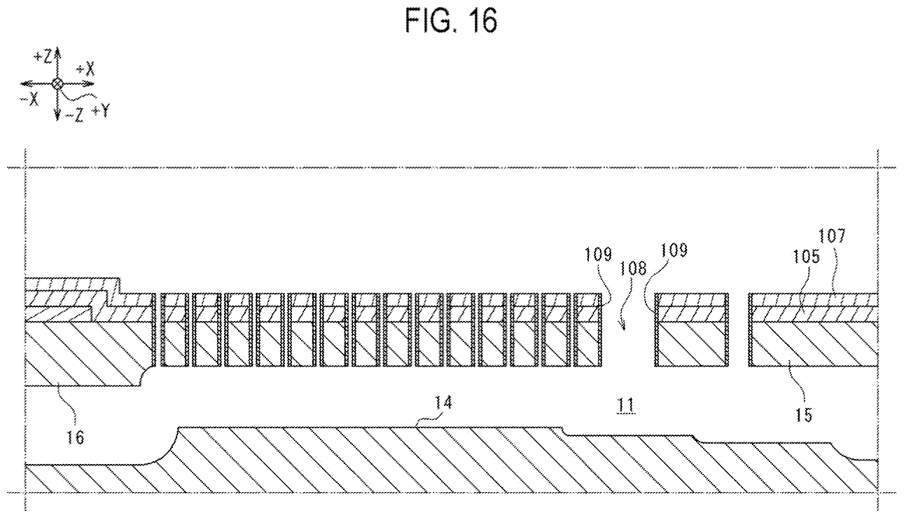

Next, as shown in FIG. 16, the bottom of the trench 108 is further dug by anisotropic etching using the second insulating film 107 as a mask. As a result, an exposed space in which a crystal plane of the first semiconductor wafer 101 is exposed is formed at the bottom of the trench 108. Subsequent to the anisotropic etching, reactive ions and an etching gas are supplied to the exposed space of the trench 108 by isotropic etching. As a result, due to the action of the reactive ions and the like, the first semiconductor wafer 101 is etched in the thickness direction of the first semiconductor wafer 101 starting from each exposed space, and is etched in the direction parallel to the surface of the first semiconductor wafer 101.

As a result, in the device region Ed, all adjacent exposed spaces are integrated to form a cavity 11 inside the first semiconductor wafer 101. In the cavity 11, the movable electrode 20 is in a floating state by being supported by the first support 15 with respect to the first peripheral wall 12. Similarly, in the cavity 11, the fixed electrode 30 is in a floating state by being supported by the second support 16 with respect to the second peripheral wall 13. Further, the isolator 50 is formed to protrude into the cavity 11 while traversing the first support 15 and the second support 16 in the Y direction and the Z direction, respectively.

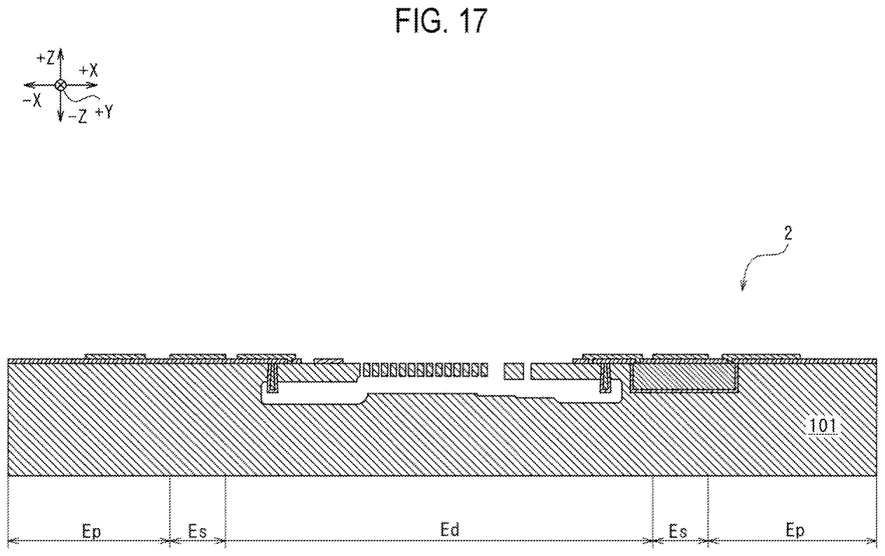

Finally, as shown in FIG. 17, the second insulating film 107 and the protective film 109 are removed by etching to complete the device-side substrate assembly 2.

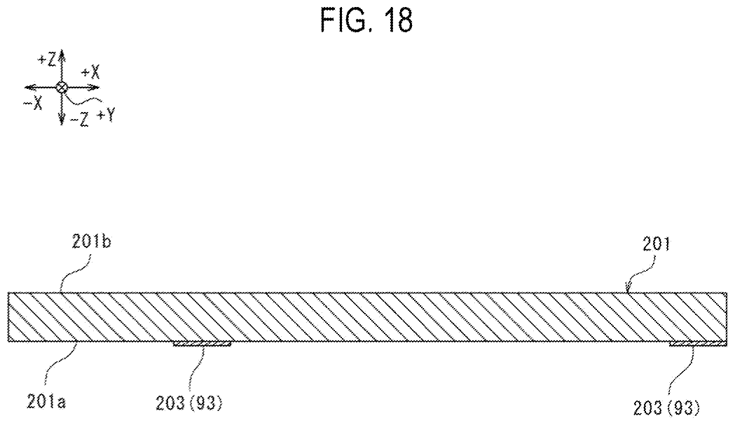

Next, a method of manufacturing the lid-side substrate assembly 3 will be described with reference to FIGS. 18 to 21. As shown in FIG. 18, a second semiconductor wafer 201, which is an original substrate of a semiconductor substrate, is provided. The second semiconductor wafer 201 is a conductive wafer, for example, a conductive silicon wafer.

The second semiconductor wafer 201 has a first main surface 201a and a second main surface 201b corresponding to the first main surface 90a and the second main surface 90b of the lid-side substrate 90, respectively. A metal film 203 is deposited over the entire first main surface 201a of the second semiconductor wafer 201 by, for example, a sputtering method. The metal film 203 is then patterned by photolithography and etching to form a bonding pad 93.

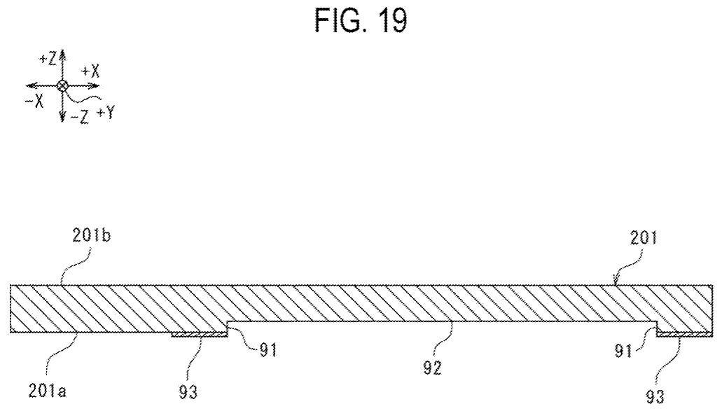

Next, as shown in FIG. 19, by selectively digging down the inner region of the bonding pad 93 of the second semiconductor wafer 201 from the first main surface 201a, a recess 92 is formed and a peripheral bank 91 is formed.

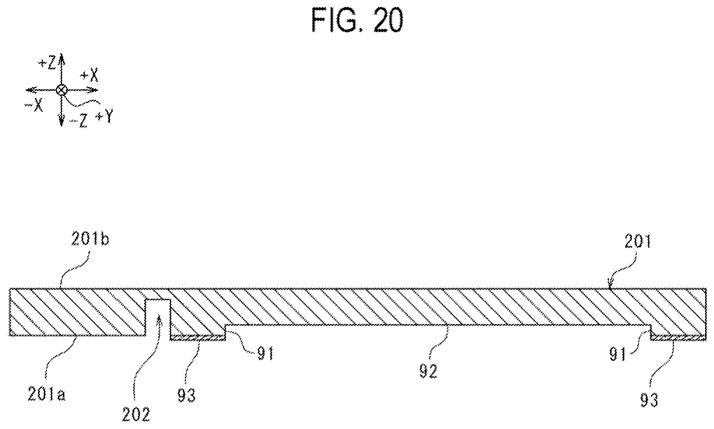

Next, as shown in FIG. 20, a trench 202 is formed on the opposite side of the peripheral bank 91 of the second semiconductor wafer 201 from the recess 92 by selective etching. The trench 202 is used to cut an end of the second semiconductor wafer 201 to expose the pad 40 when the lid-side substrate assembly 3 is bonded to the device-side substrate assembly 2.

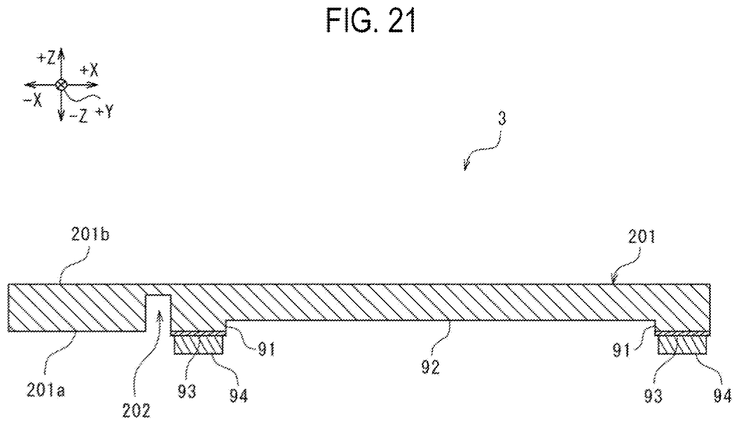

Next, as shown in FIG. 21, a bonding material 94 is printed on the bonding pads 93. Thus, the lid-side substrate assembly 3 is completed.

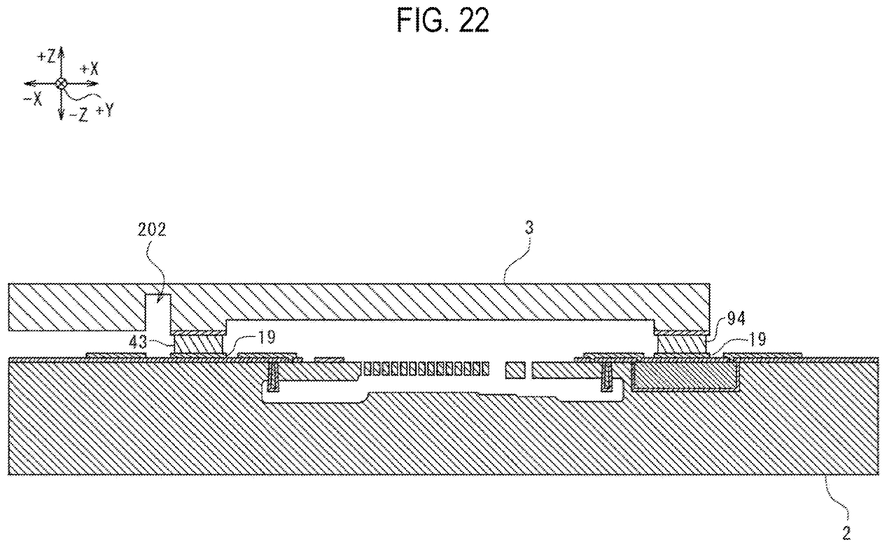

Next, a process of bonding the device-side substrate assembly 2 and the lid-side substrate assembly 3 will be described. As shown in FIG. 22, the lid-side substrate assembly 3 is aligned with the device-side substrate assembly 2 and then the lid-side substrate assembly 3 is pressed toward the device-side substrate assembly 2. As a result, the entire bonding material 94 is brought into close contact with the bonding layer 19 of the device-side substrate assembly 2, whereby the device-side substrate assembly 2 and the lid-side substrate assembly 3 are bonded together.

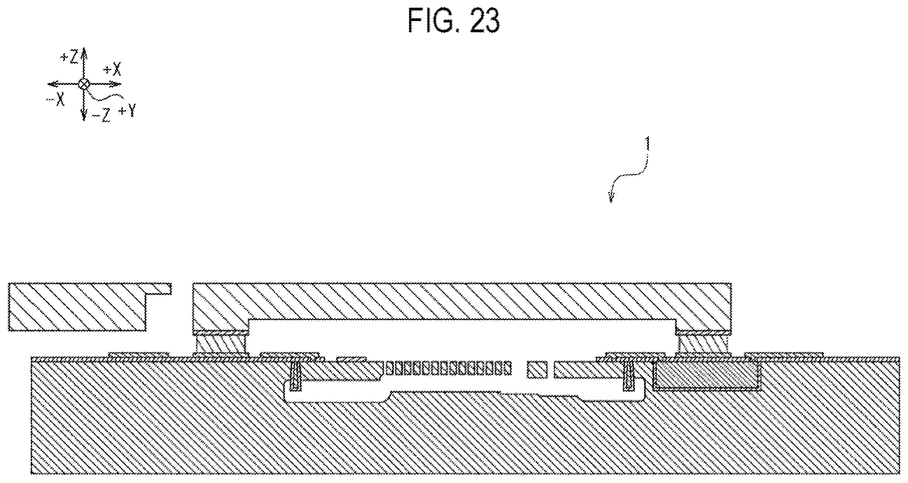

Next, as shown in FIG. 23, by selectively cutting unnecessary portions of the lid-side substrate assembly 3 (portions located on the opposite side of the trench 202 from the recesses 92), the pad 40 of the device-side substrate assembly 2 is exposed. Thus, the MEMS sensor 1 is manufactured.

According to the MEMS sensor 1 and the manufacturing method thereof according to the embodiments of the present disclosure described above, the following effects may be obtained.

(1) A MEMS sensor 1 includes a conductive device-side substrate 10 including a cavity 11 in a thickness direction of the conductive device-side substrate 10, a sensor 5 including a movable electrode 20 and a fixed electrode 30 which are MEMS electrodes arranged in the cavity 11, a first support 15 and a second support 16 extending in an X direction toward the sensor 5 from a first peripheral wall 12 and a second peripheral wall 13 of the cavity 11 and connected to the sensor 5 to support the sensor 5, and an isolator 50 configured to traverse the first support 15 and the second support 16 in a Y direction in a plan view to electrically insulate the first support 15 and the second support 16 in an X direction. The isolator 50 includes a trench 51 recessed in the thickness direction with respect to the device-side substrate 10, trench insulating layers 52 formed on inner wall surfaces of the trench 51, and trench joining layers 53 further formed on the trench insulating layers 52 and including portions facing each other in the X direction and at least partially joined to each other in the X direction.

According to the embodiments of the present disclosure, in the isolator 50, the seam 110 between the trench insulating layers 52 (a trench first thermal oxide film 103a and a trench second thermal oxide film 103b) facing each other in the X direction is joined in the X direction by the trench joining layers 53. Therefore, it is possible to suppress breakage of the isolator 50 along the seam 110.

(2) The trench insulating layers 52 may be easily formed of silicon oxide films.

(3) The trench joining layers 53 may be easily formed of polysilicon.

(4) The trench joining layers 53 are joined at least on the side of a first main surface 101a of a first semiconductor wafer 101 in the trench 51. According to the embodiments of the present disclosure, the seam 110 is joined at least in the X direction on the side of an opening of the trench 51. Therefore, it is possible to further suppress breakage of the isolator 50 along the seam, as compared with a case where the seam is joined on the bottom side.

(5) The MEMS sensor 1 further includes a lid-side substrate 90 connected to the device-side substrate 10 to form an accommodation space Z in which the sensor 5 is accommodated between the device-side substrate 10 and the lid-side substrate 90, a pad 40 configured to take out an electric signal from the sensor 5 outside the accommodation space Z, and a conductive path 60 configured to electrically connect the sensor 5 and the pad 40. The conductive path 60 includes an inner conductive path 70 embedded in the device-side substrate 10. According to the embodiments of the present disclosure, the conductive path 60 may be formed on the device-side substrate 10 while suppressing an increase in thickness.

(6) The inner conductive path 70 includes a trench 71 recessed in the thickness direction with respect to the device-side substrate 10, trench insulating layers 72 formed on inner wall surfaces of the trench 71, and trench conductive layers 73 further formed on the trench insulating layers 72. According to the embodiments of the present disclosure, the inner conductive path 70 can be easily formed.

(7) The trench insulating layers 72 may be easily formed of silicon oxide films.

(8) The trench conductive layers 73 may be easily formed of conductive polysilicon.

(9) The inner conductive path 70 has a surface flush with a surface of the device-side substrate 10 in the thickness direction of the device-side substrate 10. The MEMS sensor further includes a main insulating layer 17 formed over the first main surface 10a of the device-side substrate 10 and the surface of the inner conductive path 70, and a bonding layer 19 further formed on the main insulating layer 17 and bonded to the lid-side substrate 90. The inner conductive path 70 traverses the bonding layer 19 in a plan view. According to the embodiments of the present disclosure, the surface extending over the device-side substrate 10 and the inner conductive path 70 may be formed to be flat. Therefore, the main insulating layer 17 may be further formed to be flat over the first main surface 10a of the device-side substrate 10 and the inner conductive path 70. Further, it is easy to form the bonding layer 19 to be flat on the flat main insulating layer 17. Accordingly, the lid-side substrate 90 may be easily bonded to the device-side substrate 10 via the flat bonding layer 19. Moreover, even when the main insulating layer 17 is laminated over the inner conductive paths 70 adjacent to each other in the Y direction, passivation coverage for the inner conductive paths 70 of the main insulating layer 17 is improved because the inner conductive paths 70 are formed to be flush with the first main surface 10a of the device-side substrate 10 as described above. Accordingly, it is easy to prevent conduction between the adjacent inner conductive paths 70.

(10) The inner conductive path 70 extends from a position facing an inside of the accommodation space Z to a position facing an outside of the accommodation space Z in a plan view. According to the embodiments of the present disclosure, the inner conductive path 70 may suppress unevenness of the surface of the device-side substrate 10 in the boundary region between the inside and the outside of the accommodation space Z, thus causing the lid-side substrate 90 to be easily bonded to the surface.

(11) The inner conductive path 70 extends in the X direction traversing the bonding layer 19 and includes inner wall surfaces facing each other in the Y direction. At least portions of the trench conductive layers 73 further formed on the trench insulating layers 72 formed on the opposing inner wall surfaces are joined in the Y direction. According to the embodiments of the present disclosure, the inner conductive path 70 has a seam between the trench insulating layers 72 facing each other in the Y direction, and the seam is joined in the Y direction by the trench conductive layer 73. Therefore, it is possible to suppress breakage of the inner conductive path 70 along the seam.

(12) The trench conductive layer 73 is joined at least on the side of the first main surface 10a of the device-side substrate 10 in the trench 71. According to the embodiments of the present disclosure, the seam is joined on the side of an opening of the trench 71. Therefore, it is possible to further suppress breakage of the inner conductive path 70 along the seam, as compared with the case where the seam is joined on the bottom side.

(13) The pad 40 is formed on the main insulating layer 17, and the MEMS sensor further includes a pad wiring 62 formed on the main insulating layer 17 and extending from a pad wiring first end 62a, which is formed on the main insulating layer 17 and connected to the pad 40, to a pad wiring second end 62b facing the inner conductive path 70 in a plan view, and a third contact (pad wiring contact) 83 penetrating the main insulating layer 17 to electrically connect the pad wiring second end 62b and the inner conductive path 70. According to the embodiments of the present disclosure, the inner conductive path 70 embedded in the device-side substrate 10 and the pad 40 formed on the surface of the device-side substrate 10 may be electrically connected via the main insulating layer 17.

(14) The MEMS sensor 1 further includes a first support 15 and a second support 16 extending in the X direction toward the sensor 5 from the first peripheral wall 12 and the second peripheral wall 13 of the cavity 11 and connected to the sensor 5 to support the sensor 5, an isolator 50 configured to traverse the first support 15 and the second support 16 in the Y direction to electrically insulate the first support 15 and the second support 16 in the X direction in a plan view, a MEMS electrode wiring 61 formed on the main insulating layer 17 and extending from a MEMS electrode wiring first end 61a facing closer to the sensor 5 than the isolator 50 in the first support 15 and the second support 16 in a plan view to a MEMS electrode wiring second end 61b facing the inner conductive path 70, a first contact 81 (MEMS electrode wiring first contact) penetrating the main insulating layer 17 to electrically connect a portion of the first support 15 and the second support 16 located on the side of the sensor 5 to the MEMS electrode wiring first end 61a, and a second contact 82 (MEMS electrode wiring second contact) penetrating the main insulating layer 17 to electrically connect the inner conductive path 70 to the MEMS electrode wiring second end 61b . According to the embodiments of the present disclosure, the inner conductive path 70 embedded in the device-side substrate 10 and the MEMS electrode wiring 61 formed on the side of the first main surface 10a of the device-side substrate 10 via the main insulating layer 17 may be electrically connected to each other.

(15) A MEMS sensor manufacturing method includes: forming a trench 51 traversing in a Y direction a conductive path extending in an X-direction from a sensor 5 including a movable electrode 20 and a fixed electrode 30, which are MEMS electrodes, on a device-side substrate 10; forming trench insulating layers 52 on inner wall surfaces of the trench 51; forming trench joining layers 53 on the trench insulating layers 52 to be at least partially joined to each other in the X direction; and bonding a lid-side substrate 90 to the device-side substrate 10 to cover the sensor 5. According to the embodiments of the present disclosure, in the isolator 50, the seam 110 between the trench insulating layers 52 (a trench first thermal oxide film 103a and a trench second thermal oxide film 103b) facing each other in the X direction is joined in the X direction by the trench joining layers 53. Therefore, it is possible to suppress breakage of the isolator 50 along the seam 110.

(16) The trench joining layers 53 are annealed. This makes it easier to join the trench joining layers 53 together and makes it possible to further prevent breakage of the isolator 50 along the seam 110.

(17) A MEMS sensor manufacturing method includes: forming a trench 71 extending in an X direction on a device-side substrate 10 at a part of a conductive path extending in the X direction to a pad 40 configured to take out an electric signal from a sensor 5 including a movable electrode 20 and a fixed electrode 30, which are MEMS electrodes; forming trench insulating layers 72 on inner wall surfaces of the trench 71; forming trench conductive layers 73 on the trench insulating layers 72; and bonding a lid-side substrate 90 to the device-side substrate 10 to cover the sensor 5. According to the embodiments of the present disclosure, the conductive path 60 may be formed on the device-side substrate 10 while suppressing an increase in thickness.

(18) When manufacturing the device-side substrate 10, the trenches 51 and 71 are simultaneously formed on the first semiconductor wafer 101, the trench insulating layers 52 and 72 are simultaneously formed on the inner wall surfaces of the trenches 51 and 71, and the trench joining layers 53 and the trench conductive layers 73 are simultaneously formed on the trench insulating layers 52 and 72, thereby forming the isolator 50 and the inner conductive path 70 simultaneously. According to the embodiments of the present disclosure, the isolator 50 and the inner conductive path 70 are formed simultaneously, and therefore the number of steps may be reduced as compared with the case where the isolator 50 and the inner conductive path 70 are formed in separate steps. As a result, the MEMS sensor 1 may be efficiently manufactured, and manufacturing cost may be reduced because, for example, it is possible to integrate masks used when forming the isolator 50 and the inner conductive path 70 by etching respectively.

The present disclosure is not limited to the above-described embodiments, and various modifications may be made.

In the above-described embodiments of the present disclosure, the annealing process is performed after the polysilicon 104 is deposited by the CVD method. However, the annealing process may not be performed when the portions of the polysilicon 104 facing each other are bonded to each other in the trenches 51 and 71.

According to the above-described embodiments of the present disclosure, in the isolator, the seam between the insulating layers facing each other in the first direction is joined in the first direction by the joining layer. Therefore, it is possible to suppress breakage of the isolator along the seam.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A MEMS sensor, comprising:
a conductive device-side substrate including a cavity in a thickness direction of the conductive device-side substrate;
a MEMS electrode arranged in the cavity;
a support extending in a first direction toward the MEMS electrode from a peripheral wall of the cavity and connected to the MEMS electrode to support the MEMS electrode; and
an isolator configured to traverse the support in a second direction intersecting the first direction in a plan view to isolate the support into a first support on the side of the MEMS electrode and a second support on the side of the device-side substrate such that the first support and the second support are electrically insulated from each other in the first direction,
wherein the isolator includes:
a trench recessed in the thickness direction with respect to the device-side substrate;
insulating layers formed on inner wall surfaces of the trench; and
joining layers formed on the insulating layers and including portions facing each other in the first direction and at least partially joined to each other in the first direction.

2. The MEMS sensor of claim 1, wherein the insulating layers are silicon oxide films.

3. The MEMS sensor of claim 1, wherein the joining layers are formed of polysilicon.

4. The MEMS sensor of claim 1, wherein the joining layers are joined at least on the side of an opening of the trench.

5. The MEMS sensor of claim 1, further comprising:
a lid-side substrate connected to the device-side substrate to form an accommodation space in which the MEMS electrode is accommodated between the device-side substrate and the lid-side substrate;
a pad configured to take out an electric signal from the MEMS electrode outside the accommodation space; and
a conductive path configured to electrically connect the MEMS electrode and the pad,
wherein the conductive path includes an inner conductive path embedded in the device-side substrate.

6. A MEMS sensor, comprising:
a conductive device-side substrate including a cavity in a thickness direction of the conductive device-side substrate;
a MEMS electrode arranged in the cavity;
a lid-side substrate connected to the device-side substrate to form an accommodation space in which the MEMS electrode is accommodated between the device-side substrate and the lid-side substrate;
a pad configured to take out an electric signal from the MEMS electrode outside the accommodation space; and
a conductive path configured to electrically connect the MEMS electrode and the pad,
wherein the conductive path includes an inner conductive path embedded in the device-side substrate.

7. The MEMS sensor of claim 6, wherein the inner conductive path includes a trench recessed in the thickness direction with respect to the device-side substrate, insulating layers formed on inner wall surfaces of the trench, and conductive layers formed on the insulating layers.

8. The MEMS sensor of claim 7, wherein the insulating layers are silicon oxide films.

9. The MEMS sensor of claim 7, wherein the conductive layers are formed of conductive polysilicon.

10. The MEMS sensor of claim 7, wherein the inner conductive path has a surface flush with a surface of the device-side substrate in the thickness direction of the device-side substrate.

11. The MEMS sensor of claim 7, wherein the inner conductive path extends from a position facing an inside of the accommodation space to a position facing an outside of the accommodation space in a plan view.

12. The MEMS sensor of claim 7, further comprising:
a main insulating layer formed over a surface of the device-side substrate and a surface of the inner conductive path; and
bonding layers formed on the main insulating layer and bonded to the lid-side substrate,
wherein the inner conductive path traverses the bonding layers in a plan view.

13. The MEMS sensor of claim 12, wherein the inner conductive path extends in a first direction traversing the bonding layers and includes inner wall surfaces facing each other in a second direction intersecting the first direction, and
wherein at least portions of the conductive layers formed on the insulating layers formed on the inner wall surfaces are joined in the second direction.

14. The MEMS sensor of claim 12, wherein the conductive layers are joined at least on the side of an opening of the trench.

15. The MEMS sensor of claim 12, wherein the pad is formed on the main insulating layer, and
wherein the MEMS sensor further comprises:
a pad wiring formed on the main insulating layer and extending from a pad wiring first end connected to the pad to a pad wiring second end facing the inner conductive path in a plan view; and
a pad wiring contact penetrating the main insulating layer to electrically connect the pad wiring second end and the inner conductive path.

16. The MEMS sensor of claim 12, further comprising:
a support extending in a third direction toward the MEMS electrode from a peripheral wall of the cavity and connected to the MEMS electrode to support the MEMS electrode;
an isolator configured to traverse the support in a fourth direction intersecting the third direction in a plan view to isolate the support into a first support on the side of the MEMS electrode and a second support on the side of the device-side substrate such that the first support and the second support are electrically insulated from each other in the third direction;
a MEMS electrode wiring formed on the main insulating layer and extending from a MEMS electrode wiring first end, which faces closer to the MEMS electrode than the isolator in the support in a plan view, to a MEMS electrode wiring second end facing the inner conductive path;
a MEMS electrode wiring first contact penetrating the main insulating layer to electrically connect a portion of the support located on the side of the MEMS electrode to the MEMS electrode wiring first end; and
a MEMS electrode wiring second contact penetrating the main insulating layer to electrically connect the inner conductive path to the MEMS electrode wiring second end.

17. The MEMS sensor of claim 16, wherein the isolator includes a trench recessed in the thickness direction with respect to the device-side substrate, the insulating layers formed on the inner wall surfaces of the trench, and joining layers formed on the insulating layers and including portions facing each other in the third direction and at least partially joined to each other in the third direction.

18. A MEMS sensor manufacturing method, comprising:
forming a trench on a device-side substrate, the trench traversing a conductive path extending in a first direction from a MEMS electrode, in a second direction intersecting the first direction;
forming insulating layers on inner wall surfaces of the trench;
forming joining layers on the insulating layers to include portions facing each other in the first direction and at least partially joined to each other in the first direction; and
bonding a lid-side substrate to the device-side substrate to cover the MEMS electrode.

19. The method of claim 18, wherein the joining layers are annealed.

20. A MEMS sensor manufacturing method, comprising:
forming a trench extending in a first direction on a device-side substrate at a part of a conductive path extending in the first direction to a pad configured to take out an electric signal from a MEMS electrode;
forming insulating layers on inner wall surfaces of the trench;
forming conductive layers on the insulating layers; and
bonding a lid-side substrate to the device-side substrate to cover the MEMS electrode.
